(19) United States
(12) Patent Application Publication
(10) Pub. No.: US 2025/0309606 A1
(43) Pub. Date: Oct. 2, 2025

(54) PULSED LASERS AND METHODS OF OPERATION

(71) Applicant: ASML Netherlands B.V., Veldhoven (NL)

(72) Inventor: Christo Johannes Liebenberg, San Marcos, CA (US)

(21) Appl. No.: 18/866,267

(22) PCT Filed: Mar. 29, 2023
(86) PCT No.: PCT/EP2023/058216

§ 371 Date: Nov. 15, 2024

Related U.S. Application Data
(60) Provisional application No. 63/346,645, filed on May 27, 2022.

(51) Int. Cl. H01S 3/1123; G03F 7/00; H01S 3/10; H01S 3/106; H01S 3/107; H01S 3/223

(52) U.S. Cl. CPC H01S 3/1123; G03F 7/70025; H01S 3/10092; H01S 3/1068; H01S 3/107; H01S 3/2232

(57) ABSTRACT

A method of operating a laser includes, after a laser produces a first pulse, setting an attenuation of an attenuator in the laser such that gain of the laser exceeds losses of the laser to allow the laser to produce a first continuous beam; after the first continuous beam is produced, increasing the attenuation such that losses of the laser exceed a gain of the laser; and after increasing the attenuation, lowering the attenuation such that the laser produces a second pulse. A system for generating a pulse of laser radiation includes an optical modulator controlled by a signal applied to the optical modulator, the modulator connected to a laser, and a control system configured to provide the signal to the modulator according to the method.

### CROSS REFERENCE TO RELATED APPLICATIONS

This application claims priority to U.S. Application No. 63/346,645, filed May 27, 2022, titled PULSED LASERS AND METHODS OF OPERATION, which is incorporated herein in its entirety by reference.

### TECHNICAL FIELD

The present invention relates generally to pulsed lasers and methods of operation of pulsed lasers, and more specifically to Q-switched seed lasers in extreme ultraviolet light sources methods of their operation.

### BACKGROUND

The semiconductor industry continues to develop lithographic technologies with which to print ever-smaller integrated circuit dimensions. Use of shorter wavelengths of light, such as extreme ultraviolet (EUV) light (also sometimes referred to as soft x-rays and generally defined to be electromagnetic radiation having wavelengths of between 10 and 120 nanometers (nm)) can enable smaller features than longer wavelengths.

Presently, EUV lithography generally employs EUV light at wavelengths in the range of 10 to 14 nanometers (nm) to produce features as small as 10 nm or even 7 nm on or in substrates such as silicon wafers. To be commercially useful, it is desirable that the systems that produce these very small features be highly reliable and provide cost effective throughput and reasonable process latitude.

Methods to produce EUV light include, but are not necessarily limited to, converting a material into a plasma state that has one or more elements, e.g., xenon, lithium, tin, indium, antimony, tellurium, aluminum, etc., with one or more emission line(s) in the EUV range. In one such method, often termed laser produced plasma (LPP), the required plasma can be produced by irradiating a target material, such as a droplet, stream, or cluster of material capable of producing the desired line emission, with a laser beam at an irradiation site. The line-emitting material can be an element and can be delivered to the irradiation site in pure form or in alloy form, for example, in an alloy form that is a liquid at desired temperatures, or can be mixed or dispersed with another material such as a liquid.

In some LPP systems, respective targets in a target stream are irradiated by respective laser pulses to form a plasma from each target. Alternatively, each target can be sequentially illuminated by more than one light pulse. In some cases, each target can be exposed to a so-called “pre-pulse” to heat, expand, gasify, vaporize, and/or ionize the target material and/or generate a weak plasma, followed by a so-called “main pulse” to generate a strong plasma and convert most or all of the pre-pulse affected material into plasma and thereby produce EUV light. It will be appreciated that the functions of the pre-pulse and the main pulse can overlap to some extent.

Since EUV output power in an LPP system generally scales with the laser power that irradiates the target material, laser pulses having high power are needed. On the other hand, synchronizing pulses with targets to be irradiated, so that they meet at the desired irradiation site at the desired time, requires precise pulse timing. Given the need for both high power and precision control in the pulses used for irradiation of the targets, it can be useful to employ an arrangement including a relatively low power “seed laser” and one or more amplifiers to amplify pulses from the seed laser. The use of one or more amplifiers allows for the use of a well-controlled but relatively low power seed laser for precise timing control, while still providing, through amplification, relatively high-power pulses for the LPP process.

Even with the use of a seed laser and amplifiers, however, it is still desirable to generate a relatively higher-power seed laser pulse so that the need for amplification is lessened, or so that higher power pulses can be produced from the same amplifier(s) or amplifier system.

### SUMMARY

In some general aspects, method of operating a laser includes (1) after a laser produces a first pulse, setting an attenuation of an attenuator in the laser to a first attenuation value such that gain of the laser exceeds losses of the laser to allow the laser to produce a first continuous beam; (2) after the first continuous beam is produced, increasing the attenuation of the attenuator to a second attenuation value such that losses of the laser exceed a gain of the laser; and (3) after increasing the attenuation to the second value, lowering the attenuation of the attenuator to a third attenuation value such that the laser produces a second pulse. Implementations of the method can include also include, after the laser produces the second pulse, setting the attenuation to the first attenuation value. In implementations, the second value can shutter the laser.

Implementations of the method the method can include one or more of the following. After setting the attenuation to the second attenuation value and before setting the attenuation to the third attenuation value, lowering the attenuation to an intermediate attenuation value higher than the third attenuation value and low enough to allow the laser to produce a second beam. The attenuator can be or can include an optical modulator within or connected to the laser. The attenuator can be or can include an acousto-optic modulator (AOM) within or connected to the laser. Setting the attenuation of the attenuator can include setting an RF power level supplied to the AOM. Increasing the attenuation of the attenuator can include increasing the RF power supplied to the AOM. Lowering the attenuation of the attenuator can include lowering the RF power supplied to the AOM. The attenuator can be or can include an electro-optic modulator (EOM) within or connected to the laser. The laser can be a CO₂ laser. The laser can be a seed laser in an extreme ultraviolet (EUV) light source and/or a main pulse seed laser in an EUV light source.

Setting the attenuation to the second attenuation value can include setting the attenuation to the second attenuation value for a time in the range of 100 to 1000 nanoseconds (ns). Setting the attenuation to the intermediate attenuation value can include setting the attenuation to the intermediate attenuation value for a time in the range of 0 to 300 ns. Setting the attenuation to the third attenuation value can include setting the attenuation to the third value for a time duration in the range of 400 to 700 ns.

Implementations of the method can also include one or more of the following. Monitoring a duration from the first pulse to the production of the first continuous beam and adjusting a cavity length of the laser to minimize the duration. Monitoring a duration between the first pulse to the production of the first continuous beam and adjusting the first attenuation value based on the duration.

The third attenuation value can be a maximum attenuation value. The first attenuation value can be equal to the third attenuation value. (1) increasing the attenuation of the attenuator to a second attenuation value such that losses of the laser exceed a gain of the laser, and (2) after increasing the attenuation to the second value, lowering the attenuation of the attenuator to a third attenuation value such that the laser produces a second pulse, is or can include Q-switching the laser.

In additional general aspects, a method of operating a laser including an optical modulator controlled by a signal applied to the optical modulator can include (1) setting a magnitude of the signal to a first value such that the laser operates in a mode in which laser gain exceeds resonator losses; (2) setting a magnitude of the signal to a second value such that the laser is shuttered; and (3) setting a magnitude of the signal to a third value such that the laser produces a pulse.

Implementations of the method can include one or more of the following. The laser can include an output coupler having a piezoelectric transducer, and the method can include using an output of the laser to control a voltage applied to the piezoelectric transducer during the step of setting a magnitude of the signal to a first value.

The optical modulator can be or can include an acousto-optic modulator (AOM). The signal can be an RF power level applied to the AOM. The optical modulator can be or can include an electro-optic modulator (EOM). (1) setting a magnitude of the signal to a second value such that the laser is shuttered, and (2) setting a magnitude of the signal to a third value such that the laser produces a pulse, is or can include Q-switching the laser.

In another general aspect, a system for generating a pulse of laser radiation includes (1) a laser including an optical modulator controlled by a signal applied to the optical modulator; and (2) a control system configured and adapted to sequentially set a magnitude of the signal to a first value such that the laser operates in a mode in which laser gain exceeds resonator losses, then to set a magnitude of the signal to a second value such that the laser is shuttered, and then set a magnitude of the signal to a third value such that the laser produces a pulse.

Implementations of the system can include one or more of the following. The laser can include an output coupler having a piezoelectric transducer and the control system can be additionally configured and adapted to use an output of the laser when the signal is at the first value to control a voltage applied to the piezoelectric transducer.

The optical modulator can be or can include an acousto-optic modulator (AOM). The signal applied to the AOM can be an RF power level. The optical modulator can be or can include an electro-optic modulator (EOM). The control system is or can be configured and adapted to perform Q-switching.

In another general aspect, a laser system includes (a) a laser having a laser cavity; (b) an optical modulator configured to control a Q factor of the laser cavity; (c) a power sensor positioned outside the laser cavity and configured to detect a power level of radiation emitted from the laser and to produce power level data and/or signals relating to a power level of radiation emitted from the laser; and (d) a control system connected to receive the power level data or signals and to control the optical modulator, with the control system configured to (1) set the Q factor of the cavity of the laser to a first value high enough to allow lasing to occur, (2) at a time after lasing is detected by the power sensor, set the Q factor of the cavity to a second value less than the second value and low enough to stop the lasing from occurring, and (3) after setting the Q factor of the cavity to the second value, set the Q factor of the cavity to a third value such that the laser emits a pulse. The control system is or can be configured to perform Q-switching.

The details of one or more implementations are set forth in the accompanying drawings and the description below. Other features will be apparent from the description and drawings, and from the claims.

### DRAWING DESCRIPTION

FIG. 1 is a diagram of aspects of an extreme ultraviolet (EUV) light source.

FIG. 2 is a diagram of an EUV light source together with a lithography exposure apparatus.

FIG. 3 is a diagram of aspects of a seed laser module useful in an EUV light source.

FIG. 4 is a diagram of a laser useful as a seed laser in an EUV light source.

FIG. 5A is a graph of an implementation of a periodically varying Q factor for producing a periodic Q-switched pulse from a laser such as a seed laser in an EUV light source.

FIG. 5B is a graph of a periodically varying RF power level that can be applied to an AOM to produce a periodically varying Q factor such as that of FIG. 5A.

FIG. 5C is a graph of a periodically varying laser output power such as can be produced by the periodically varying Q factor of FIG. 5A and/or the periodically varying RF power of FIG. 5B.

FIG. 6A is a graph of an implementation of a periodically varying Q factor for producing a periodic Q-switched pulse having increased power output from a laser such as a seed laser in an EUV light source.

FIG. 6B is a graph of a periodically varying RF power level that can be applied to an AOM to produce a periodically varying Q factor such as that of FIG. 6A.

FIG. 6C is a graph of a periodically varying laser output power such as can be produced by the periodically varying Q factor of FIG. 6A and/or the periodically varying RF power of FIG. 6B.

FIG. 6D is a flow chart describing steps of a process for varying a Q factor in accordance with an aspect of an embodiment.

FIG. 7A is a graph of an additional implementation of a periodically varying Q factor for producing a periodic Q-switched pulse having increased peak power output from a laser such as a seed laser in an EUV light source.

FIG. 7B is a graph of a periodically varying laser output power such as can be produced by the periodically varying Q factor of FIG. 7A.

### DETAILED DESCRIPTION

The methods, apparatuses and systems of the present disclosure involve the operation Q-switched lasers. Q-switching, sometimes known as giant pulse formation, is a known technique for both controlling a laser to operate in a pulsed mode and for increasing the peak power of the laser. Q-switching allows a laser to produce pulses of much greater peak power than the peak power of pulses formed from a continuous beam, such as by switching with a beam blocker or beam diverter to form “pulses.”

Q-switching is generally achieved by putting some type of variable attenuator within the laser's optical cavity (a “Q-switch”). The Q-switch functions as a type of shutter and can, for example, be an acousto-optic modulator (AOM) or an electro-optic modulator (EOM) either of which can be adjusted by the application of a control signal to pass differing amounts of the light incident upon it. In basic Q-switching, the Q-switch is initially closed, i.e., set to pass very little or no light, which prevents the laser from lasing and allows the energy stored in the laser medium, in the form of an inversion population, to increase above levels achievable during continuous lasing. The Q-switch is then quickly opened, allowing for essentially all of the energy stored in the laser medium to be released very quickly in a relatively short pulse.

For example, using Q-switching, a laser might generate pulses that are each ½ microsecond (μs) long at a rate in the range of 50,000 to 100,000 times per second (50 to 100 kHz), thus allowing power to build up for about 10 to 20 μs between pulses. In this way, a laser that can generate, for example, 50 watts of power in continuous lasing, can generate, for instance, pulses having peak power of 500 watts to 1 kW.

Q-switching as described above can suffer from some timing variability. When the Q-switch is opened, allowing the Q-switched pulse to be emitted, there is a statistical uncertainty as to when the first photon(s) (the first light) will begin to be emitted along the optical path within the cavity of the laser. Thus the precise timing of the Q-switched pulse itself is slightly variable and not as predictable as would be desired. For example, there can be little or no energy emitted by a laser upon opening a Q-switch for 100 to 200 nanoseconds (ns) and sometimes for as long as 400 ns. This variation in the timing of the beginning of the Q-switched pulse, sometimes known as “temporal jitter,” is not a shutter problem, as the timing of the operation of the Q-switch shutter effect of an AOM or an EOM, for example, is not significantly variable. Yet the timing of the beginning of lasing is variable.

One modification of Q-switching is to use “pre-lasing” i.e., to allow the laser to lase continuously at a low level before Q-switching. Generally, to allow pre-lasing, the Q-switch (the attenuator) is not completely “closed” during the time between pulses (the “inter-pulse interval), but rather is set to provide partial attenuation of laser energy. Onset of pre-lasing after a Q-switched pulse also suffers from temporal jitter, but if pre-lasing is already occurring when the Q-switch is opened wide (i.e., when the attenuation of the attenuator is reduced to zero or to a low value), a large Q-switched pulse will occur essentially immediately, without any significant temporal jitter. Thus when pre-lasing is used, the timing of the Q-switched pulse is significantly more predictable than in ordinary Q-switching.

In Q-switching with the use of pre-lasing, the amount of the partial attenuation present after a pulse determines an average level of stored power needed in the laser before pre-lasing next begins. So the less attenuation there is by the Q-switch, the sooner the pre-lasing begins, on average, after a previous Q-switched pulse.

Between pulses, the Q-switch or attenuator is ideally set at a level that does not use very much power during pre-lasing, i.e., a relatively high attenuation level, so that the small signal gain can build up as much as possible for use in the Q-switched pulse.

Despite the use of relatively low attenuation for pre-lasing between pulses, the improved timing produced by Q-switching with pre-lasing comes at a cost of reduced power in the Q-switched pulse. For example, if a laser can produce a pulse of 1 kW with ordinary Q-switching, it might produce only about 500 watts or even less when pre-lasing is used.

If pre-lasing occurs too early, the gain of the laser (and the peak power of the pulses produced) will be lower, because the lower attenuation levels that produce earlier pre-lasing will result in lower total peak power buildup during pre-lasing. Thus higher inter-pulse attenuation levels that tend to delay the onset of preleasing are desirable for higher peak pulse power. But if pre-lasing occurs too late it may occasionally not occur before the Q-switch is fully opened, and a mis-timed pulse will occur, or in extreme cases a weak pulse or even no pulse at all may occur during the opening of the Q-switch. To avoid these issues, the time from a Q-switched pulse to the onset of subsequent pre-lasing can be monitored, and the attenuation of the Q-switch between pulses can be increased gradually if the pre-lasing occurs, on average, sooner than a target time, and decreased gradually if the pre-lasing occurs, on average, later than a target time.

A problem separate from and not solved by Q-switching or pre-lasing can be known as “mode instability.” In a given laser medium, a wavelength band within which light amplification can occur can be described as an “amplification band” or a “gain bandwidth” or “gain profile” and is characteristic of the laser medium. A laser cavity with a given laser medium has a number of possible “cavity modes,” or frequencies whose wavelengths evenly divide the optical length of the cavity (“resonant frequencies”) and are within the amplification band of the laser medium. The specific cavity modes available thus depend upon the optical length of the laser cavity and the amplification properties of the laser medium.

If a cavity mode falls at or near a peak of the gain profile of the laser medium, that mode will dominate the laser emission to the exclusion of other modes, and the laser will operate in “single longitudinal mode,” a state with generally high efficiency, and stable and consistent wavelength and power output. But if two cavity modes are equidistant from, or both sufficiently close to, the peak of the gain profile, multimodal (multiwavelength) operation can occur. Instability (or “mode beating”) between the two (or more) modes can then arise, giving rise to varying wavelength and power output. Even if stable multimode operation is achieved, the resulting power output is significantly reduced by the division of the available gain into two (or more) modes.

If the relationship between the optical path length of the cavity of a laser and the gain profile of the medium of the laser changes over time, such as due to a change in the cavity length due to thermal effects for example, then a single mode previously in production can lose power, and the laser can even change from single mode to multimode operation and/or become unstable, causing the available power of the laser to decrease significantly. A change in cavity length of even a few microns can have a substantial effect on the laser output power, for example.

Accordingly, the laser optical cavity can employ a movable optical component, such as a mirror in the optical cavity for example, such that moving the optical component changes the optical length of the optical cavity. The position of the optical component and the resulting cavity length can be continuously dithered (varied slightly) at a relatively high rate (relative to the rate of the above-mentioned adjustment of attenuation) during operation of the laser, while a duration from each pulse to the subsequent onset of pre-lasing is measured. The position of the optical component (or more precisely an average or reference position of the optical component such as the center position of the dithering) can then be shifted gradually toward the direction producing the shortest average duration from a pulse to the onset of the subsequent pre-lasing. Because the shortest times until pre-lasing occur (all else being equal) when a cavity mode of the laser is centered on the maximum (or peak) of the gain profile of the laser medium (producing strong single mode lasing), this method allows the laser to hold its cavity length at, or continuously adjust its cavity length toward, a length centering a cavity mode at the peak of gain, maintaining single mode operation of the laser, with resulting high efficiency and power.

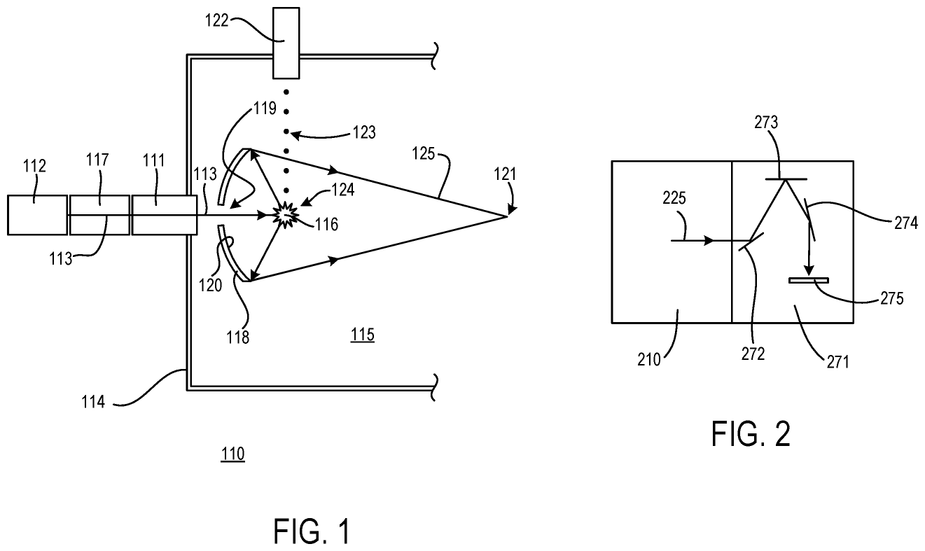

FIG. 1 is a simplified schematic view of some of the components of an embodiment of an LPP EUV light source 110. As shown in FIG. 1, the EUV light source 110 includes a laser source 112 for generating a beam of laser pulses and delivering the beam along one or more beam paths 113 from the laser source 112 and into a chamber 114 to illuminate a respective one of targets 123 at an irradiation site 116. Aspects of examples of laser arrangements that can be suitable for use in the system 112 shown in FIG. 1 are described in more detail below.

As also shown in FIG. 1, the EUV light source 110 can also include a target material delivery system 122 that delivers targets 123 into the interior 115 of the chamber 114 to the irradiation site 116, where the targets 123 will interact with one or more laser pulses to ultimately produce a plasma 124 and generate an EUV light 125.

The material of targets 123 is or includes an EUV emitting material such as, but not necessarily limited to, a material including tin, lithium, xenon, or combinations thereof. The target material can be in the form of liquid droplets, or alternatively can be solid particles or solid particles contained within liquid droplets. For example, the element tin can be presented as a target material as pure tin, as a tin compound, such as SnBr₄, SnBr₂, SnH₄, as a tin alloy, e.g., tin-gallium alloys, tin-indium alloys, or tin-indium-gallium alloys, or a combination thereof.

The EUV light source 110 can also include a collector 118 such as a near-normal incidence collector mirror having a reflective surface 120 in the form of a prolate spheroid (i.e., an ellipse rotated about its major axis), such that the optical element 118 has a first focus within or near the irradiation site 116 and a second focus at a so-called intermediate focus 121, where the EUV light 125 can be output from the EUV light source 110 and input to a device utilizing EUV light, such as a lithography exposure apparatus (shown in FIG. 2). The collector 118 is formed with an aperture 119 to allow the laser light pulses generated by the laser source 112 to pass along the beam path 113 through the aperture 119 and reach the irradiation site 116. In order to reflect EUV light, the collector surface 120 can have a graded multilayer coating with alternating layers of molybdenum and silicon, and in some cases, one or more high temperature diffusion barrier layers, smoothing layers, capping layers and/or etch stop layers. Other surface shapes can also be used for the surface 120, such as a parabola rotated about its major axis. In implementations, the surface 110 can be configured to deliver a beam having a ring-shaped cross section at the intermediate focus region 121. In other implementations, the surface 120 can utilize coatings and layers other than or in addition to those described above.

As shown in FIG. 1, the EUV light source 110 can include a focusing unit 111 which includes one or more optical elements for focusing the laser beam to a focal spot or beam waist at the irradiation site 116. EUV light source 110 can also include a beam conditioning unit 117, having one or more optical elements, between the laser source 112 and the focusing unit 111, for expanding, steering and/or shaping the laser beam and/or shaping the laser pulses.

FIG. 2 is a diagram showing an implementation of an EUV light source 210 such as EUV light source 110 or another EUV source, with a lithography exposure apparatus 271. The lithography exposure apparatus 271 receives EUV light 225 produced by the EUV light source 210 and reflects it in one or more illumination mirrors 272 so as to illuminate a reflective pattern or reticle 273. EUV light reflected from the pattern or reticle 273 is further reflected and reduced by one or more reducing mirrors 274 and irradiated on a substrate or wafer 275 (or on one or more photosensitive layers on the substrate or wafer 275, not shown) to allow the formation of patterned structures in or on the substrate or wafer 275.

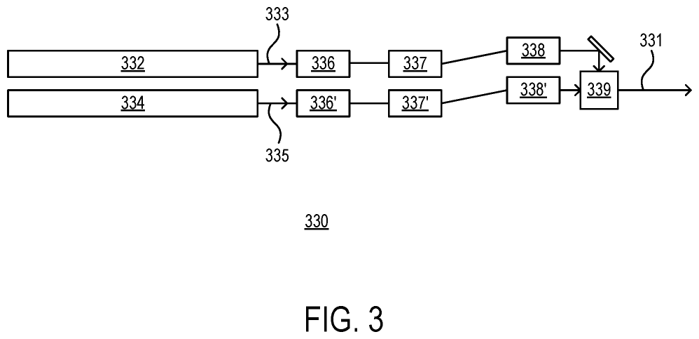

As noted above and referring again to FIG. 1, in some cases an EUV light source 110 uses one or more seed lasers to generate laser pulses, which can then be amplified to become the laser pulses that irradiate a target 123 at the irradiation site 116 to form a plasma 124 that produces the EUV light 125. FIG. 3 is a simplified schematic view some parts of an implementation of a seed laser module 330 that can be used as part of the laser source 112 in an EUV such as the EUV light source 110 of FIG. 1.

As illustrated in FIG. 3, an example implementation of a seed laser module 330 includes two seed lasers, a pre-pulse seed laser 332 and a main pulse seed laser 334. In such an implementation containing two seed lasers, a target 123 (FIG. 1) can be irradiated first by one or more pulses initiated from the pre-pulse seed laser 332 and then by one or more pulses initiated from the main pulse seed laser 334.

The seed lasers 332 and 334 contain within them relatively fragile optical components not shown in the figure, such as output couplers, polarizers, mirrors, gratings, AOMs, or EOMs, and so forth. Thus it is desirable to prevent any light that may be propagating back toward the seed lasers 332, 334, such as light reflected from a target 123 at the irradiation site 116, or light from any other source, from reaching and damaging these components or otherwise interfering with the stable operation of the seed lasers 332, 334.

In the implementation of FIG. 3, the respective beams 333, 335 in the form of pulses from each seed laser 332, 334, respectively, are first passed through a respective EOM 336, 336′. The EOMs 336, 336′ are used with the seed lasers 332, 334 as pulse shaping units to trim the pulses generated by the seed lasers into pulses having shorter duration and faster rise time and fall time. A shorter pulse duration and relatively fast fall time may increase EUV light source output and efficiency because of a short interaction time between the pulse and a target 123, and because the trimmed unneeded portions of the pulse do not enter downstream amplifiers (not shown) to deplete unnecessarily an amplifier gain of the downstream amplifiers. While two separate pulse shaping units (EOMs 336, 336′) are shown, alternatively a common pulse shaping unit may be used to trim both the pre-pulse and the main pulse seed pulses.

The beams from the seed lasers are then passed through respective AOMs 337, 337′ and 338, 338′. The AOMs 337, 337′ and 338, 338′ effectively act as one-way gates by diverting back-propagating light, from a reflection from a target 123 or elsewhere, preventing the light from reaching the seed lasers 332, 334. In the implementation shown here, the beams 333, 335 in the form of pulses from each seed laser each pass through two AOMs. Each successive AOM causes a frequency and wavelength shift in the passing beam, and the second AOM 338, 338′ on each beam path is oriented such that the shift is the opposite of the first AOM 337, 337′ and thus reverses the shift of the first AOM 337, 337′. Other implementations can employ only a single AOM on each path, or even one AOM for both paths, if desired.

After passing through the AOMs 337, 337′ and 338, 338′, the two pulses are “combined” by a beam combiner 339. Since in one implementation the pre-pulse seed laser and main pulse seed laser can have slightly different wavelengths, the beam combiner 339 can be a dichroic beam splitter. Since the pulses from each seed laser 332, 334 are generated at slightly different times, two temporally separated pulses, one from each seed laser 332, 334, are placed on a common beam path 331 for further processing and use.

After being placed on the common beam path 331, pulses from the seed lasers can pass through various components such as, for instance, a pre-amplifier, a beam expander, a polarizer, and various redirecting and/or focusing components (not shown). Following this, the pulses can pass through an amplification system typically including multiple amplifier stages (not shown) and a beam conditioning unit such as beam conditioning unit 117 of FIG. 1, before being delivered to a focusing unit such as focusing unit 111 of FIG. 1 and to a target 123.

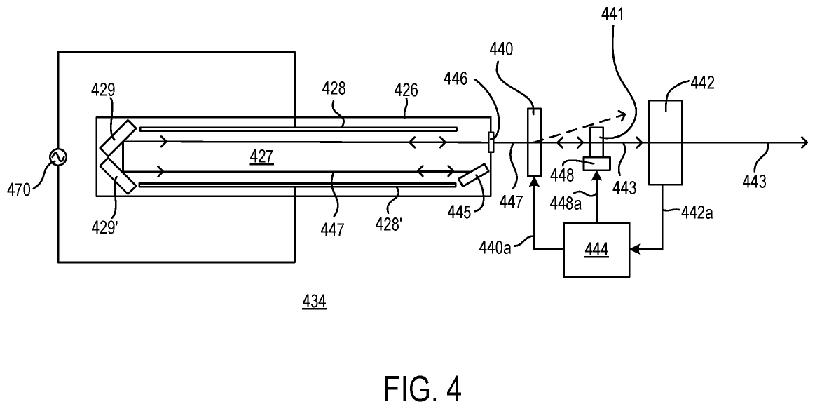

FIG. 4 is a simplified block diagram of a laser 434 which is one example of an implementation of the main pulse seed laser 332 of FIG. 3. In the laser 434 of FIG. 4, an enclosure 426 contains a laser medium (or “gain medium”) 427 held at sub-atmospheric pressure. Energy can be provided to the laser medium 427 in the form of an oscillating electrical field produced between electrodes 428, 428′ by an RF source 470. A resonant optical cavity or “resonator” is provided along an optical axis 447 by mirrors 429, 429′ and a reflective grating 445, together with a moveable output coupler or extraction mirror 441. A window 446 allows the beam to exit the enclosure 426 while retaining the laser medium 427. Lasing generally occurs when the energy added by the laser medium to a light beam travelling through one round trip of the resonator or optical cavity (the “laser gain”) matches or exceeds the energy lost by the beam in the same round trip (the “resonator losses”).

A variable attenuator or Q-switch 440, which can be in the form of an optical modulator such as an AOM or EOM, is controlled by a signal 440a from a control module or control system 444. In the case of an AOM for the Q-switch 440, the signal 440a can be an RF power level. Typically, with a low or zero RF power level applied to the AOM, low attenuation (or low resonator losses and high Q factor) results. With a high RF power level applied to the AOM, high attenuation (or high resonator losses and low Q factor) results. In the case of an EOM for the Q-switch 440, the signal 440a can be a voltage level. Whether attenuation increases or decreases with the applied voltage level depends on the design or type of the EOM. The Q-switch 440 is controlled to provide attenuation (low Q factor or high resonator losses) to allow power to build up in the seed laser 434 as described above, and is then switched to provide low or zero attenuation (high Q factor or low resonator losses) in order to Q-switch the laser 434, allowing the laser 434 to produce a pulse.

A sensor 442 measures one or more parameters of an output beam 443, such as output beam power, for example, and provides related data or signals 442a to the control module 444. The control module or control system 444 uses the data or signals 442a to determine appropriate adjustments to the Q-switch 440, such as the level of attenuation applied between pulses, and to determine certain appropriate adjustments to a length of the laser cavity 447. The control module or control system 444 sends commands or signals 448a to an actuator 448 to move the moveable extraction mirror 441 in accordance with the determined adjustments. The actuator 448 can be, or can contain as a driving element, a piezoelectric transducer (PZT). The commands or signals can be voltage levels for the PZT. The actuator 448 is able to move the moveable extraction mirror 441 over an adjustment range that includes at least 3 cavity modes.

In addition to controlling the length of the laser cavity, it is desirable to simultaneously control the timing of pre-lasing. As above, there are two factors that affect when pre-lasing begins. First, as above, the lower the Q-switch attenuation (the higher the Q factor) between pulses, the sooner the lasing threshold will be reached and pre-lasing will occur. Second, when a cavity mode is located at the peak of the gain bandwidth, effective gain will build up more quickly than when there are only offset modes away from the gain peak. Thus, when a partly open Q-switch is used to provide attenuation as described above, the lasing threshold will be reached, and pre-lasing will thus begin, sooner when a cavity mode is located at the gain peak than when only offset modes are present. Having the cavity mode located at the gain peak also results in the greatest output power from the laser.

A cavity mode of the laser 434 can be kept at or near the gain peak by the control module 444 dithering (i.e., slightly changing back and forth) the position of the mirror 441, while monitoring the duration from the Q-switched pulses to the respective subsequent onsets of pre-lasing using for example sensor 442. The position of the mirror 441 along the optical axis 447 (or more precisely the average or reference position of the mirror, such as the center position of the dithering, for example) can then be shifted gradually toward the direction producing the shortest average duration from the Q-switched pulses to the respective subsequent onsets of pre-lasing. Because the shortest durations until pre-lasing occur (all else being equal) when a cavity mode of the laser is centered on the maximum (or peak) of the gain profile, this method or process allows the laser to hold its cavity length at a position, or continuously adjust its cavity length toward a position, which centers a cavity mode at the peak of gain, maintaining single mode operation of the laser, with resulting high efficiency and power, and with shorter time to onset of pre-lasing.

Control module 444 can also adjust the time to onset of pre-lasing, over a longer timescale than the mode-centering process, by gradually increasing the inter-pulse attenuation of the Q-switch 440 if the average time to onset or pre-lasing is shorter than a target time, and gradually decreasing the inter-pulse attenuation if the average time to onset is longer than the target time. By the control module 444 adjusting the attenuation of the Q-switch 440 at a relatively gradual rate, the mode-centering process discussed above can continuously center a cavity mode at or near the gain peak during the attenuation adjustments.

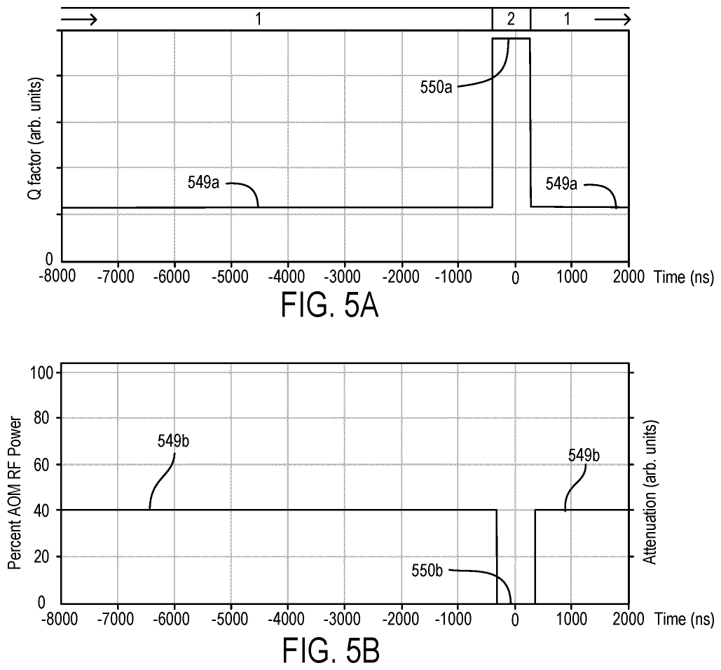

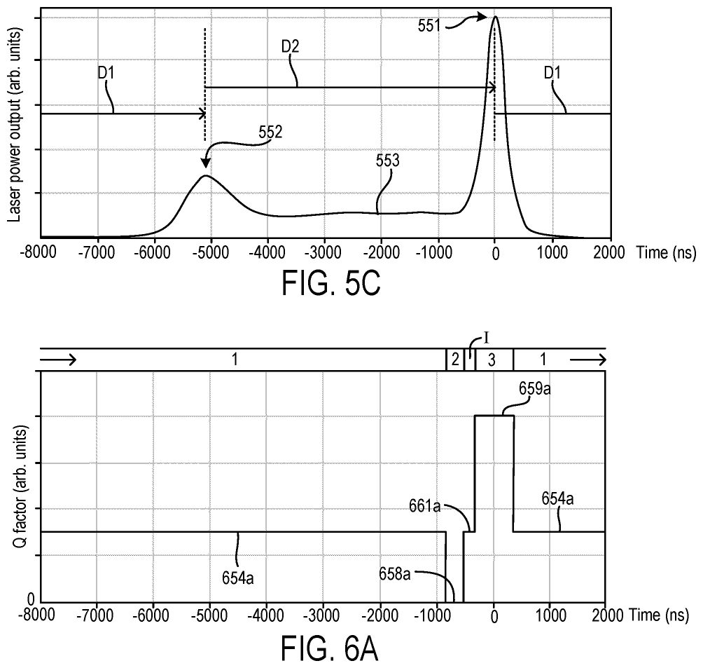

FIG. 5A is a graph of an implementation of a periodically varying Q factor, in arbitrary units, as a function of time in nanoseconds for producing a Q-switched pulse from a laser such as the laser 434 described above with reference to FIG. 4.

FIG. 5B is a corresponding graph of a periodically varying RF power which can be applied to an AOM, such as by control module 444 to Q-switch 440 of FIG. 4 (when an AOM is used for Q-switch 440), to produce the Q factor graphed in FIG. 5A or the like. As may be seen from the figures, RF power to the AOM goes inversely relative to the Q factor of the laser, and thus positively corresponds to attenuation. Accordingly, FIG. 5B can also be read and understood as a graph of attenuation (of arbitrary scale, as indicated on the right-side vertical axis) produced by the Q-switch 440 over time.

Two phases of the periodic Q factor or periodic RF power or attenuation of FIGS. 5A and 5B are indicated and labeled at the top of the graph of FIG. 5A. Since the Q factor shown in FIG. 5A and the corresponding attenuation and/or RF power to the AOM shown in FIG. 5B are periodic, they repeat from pulse to pulse of the laser. Accordingly, phase 1, as indicated by the arrows at the top of FIG. 5A, wraps around the graph, starting at the end of a preceding phase 2 and extending to the beginning of a succeeding phase 2. In this example, then, there is a 10,000 ns (or 10 μs) interval between pulses as seen from the x axis time scale in the figures, so the pulse rate shown is 100 kHz.

Beginning after the high Q factor 550a of FIG. 5A, or the low RF power or low attenuation value 550b of FIG. 5B (the Q-switching window) centered at time zero, a first Q factor 549a and corresponding first attenuation value 549b is set in phase 1. The value of the Q factor 549a or attenuation value 549b in phase 1 is set sufficiently high to allow the onset of lasing to occur (namely, at a level at which the gain of the laser medium exceeds the cavity losses of the laser) and sufficiently low to still provide attenuation to allow power buildup in the laser beyond the power level in non-attenuated continuous lasing. This phase 1 or “inter-pulse” attenuation level 549b can be adjusted as discussed above to keep the average time of onset of pre-lasing at or near a desired target time. Next in phase 2, a second Q factor 550a and/or a second RF power level or attenuation value 550b is set, such as at a maximum Q factor or a minimum attenuation for the particular laser 434, to Q-switch the laser 434 and allow a pulse to be produced.

FIG. 5C is a graph of output beam power (of arbitrary scale) resulting from the two-phase or two-level periodic attenuation of FIGS. 5A and 5B. Soon after the pulse 551 with peak at time 0, the laser output falls to near zero, even though the attenuation in phase 1 is set as in FIGS. 5A and 5B at a value low enough to allow lasing. This is because the large Q-switched pulse at time 0 consumes virtually all of the stored energy (in the form of population inversion in the laser medium) in the laser. Only after a duration D1 does enough energy build up again to cause the onset of pre-lasing (or low-level continuous lasing) with an initial peak 552 followed by a relatively low power constant beam 553. Duration D1 is relatively shorter, as mentioned, with the higher laser efficiency produced by alignment of a cavity mode with the gain peak, and so duration D1 can be used to maintain single mode operation of the laser, varying the cavity length as needed to minimize D1 as described above. Note however that in a pulsed laser repeating at a fixed frequency, duration D1 is equivalent to the period of the repetition minus duration D2, so duration D2, from the pre-lasing peak 552 to the peak of Q-switched pulse 551, can also be used, and maximized rather than minimized, to maintain single mode operation.

As mentioned above, it is desirable to increase the power output of a Q-switched laser, particularly a seed laser in an EUV light source. More power from a seed laser of an EUV light source results in more amplified laser power delivered to targets in the EUV light source, and thus higher powers of EUV-emitting plasma, such that higher-power EUV light can be received by an associated EUV lithography exposure apparatus and by wafers under process therein, so that more wafers can be exposed in less time, producing significant time savings in a high-value process.

Higher power can potentially be produced from a given seed laser such as laser 434 of FIG. 4 by (1) increasing the frequency of pulses or (2) increasing the power of each pulse, or (3) by both in combination, but these can be difficult to achieve, particularly in combination, using the two-phase periodic attenuation variation of FIGS. 5A and 5B.

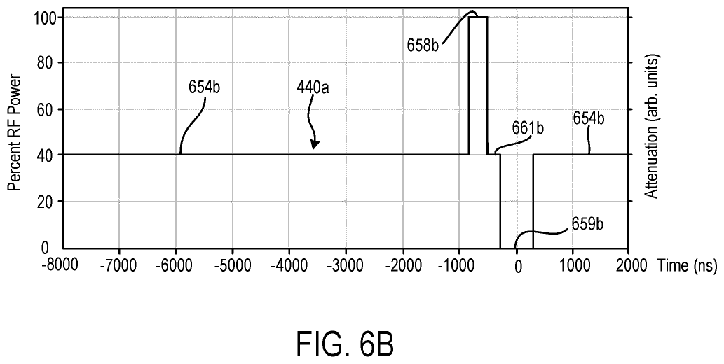

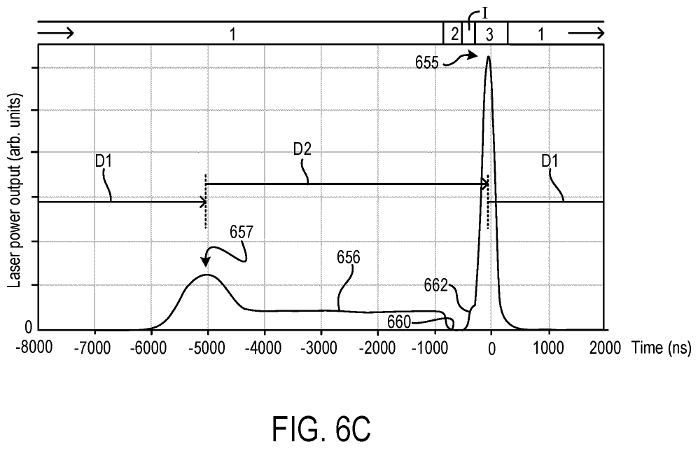

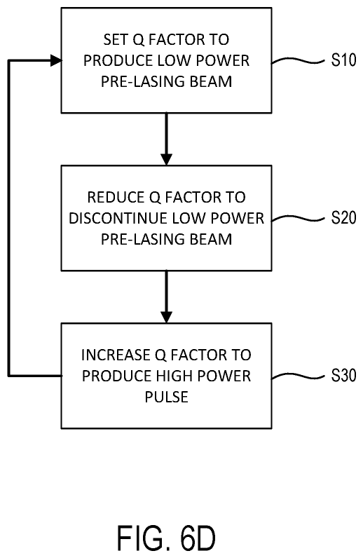

As the pulse repetition rate increases, such as from 50 kHz to the 100 kHz repetition frequency represented in FIGS. 5A-5C, there is less time between pulses for the onset of pre-lasing to occur, and there is less time for the gain to recover. To address the problems of late or no pre-lasing mentioned above, the attenuation in phase 1 of FIGS. 5A-5C can be gradually adjusted downward (thus adjusting the Q factor in phase 1 upward) to allow earlier average onset (for a shorter average of duration D1 and longer average of duration D2). With a lower attenuation (higher Q factor) in phase 1, a lower amount of energy is stored and available for use by the Q-switched pulse 551. Peak pulse power at 100 kHz can thus be lower by a factor of 2 or greater than peak pulse power at 50 kHz, for example. Higher peak pulse power can be produced at higher repetition rates by operating the laser 434 with periodic Q factor values or attenuation values of the type shown in FIGS. 6A and 6B, with periodic laser power output power such as shown in FIG. 6C.

FIG. 6A is a graph of an implementation of a periodically varying Q factor, in arbitrary units, as a function of time in nanoseconds for producing a Q-switched pulse from a laser such as the laser 434 described above with reference to FIG. 4.

FIG. 6B is a corresponding graph of a periodically varying RF power which can be applied to an AOM, such as in the form of the signal 440a by control module 444 to Q-switch 440 of FIG. 4 (when an AOM is used for Q-switch 440), to produce the Q factor graphed in FIG. 6A or the like. As may be seen from the figures and as mentioned above, RF power to the AOM goes inversely relative to Q factor of the laser, and thus positively corresponds to attenuation. Accordingly, FIG. 6B can also be read and understood as a graph of attenuation (of arbitrary scale, as indicated on the right-side vertical axis) produced by the Q-switch 440 over time.

Three phases of the periodic Q factor or periodic RF power or attenuation of FIGS. 6A and 6B are indicated and labeled 1-3 at the top of the graph of FIG. 6A, plus one optional intermediate phase labeled I. FIG. 6C is a graph of output beam power (of arbitrary scale) resulting from the three phases with intermediate phase I the periodic Q factor or periodic attenuation values of FIGS. 6A and 6B, with the phases 1-3 and I also labeled at the top of FIG. 6C.

Since the Q factor shown in FIG. 6A and the corresponding attenuation and/or RF power to the AOM shown in FIG. 6B are periodic, they repeat from pulse to pulse of the laser 434. Accordingly, phase 1, as indicated by the arrows at the top of FIG. 6A, wraps around the graph, starting at the end of a preceding phase 3 and extending to the beginning of a succeeding phase 2. As above, then, there is a 10,000 ns (or 10 μs) interval between pulses as seen from the x axis time scale in the figures, so the pulse rate shown is 100 kHz.

Beginning after the high Q factor 659a of FIG. 6A, or the low RF power or low attenuation value 659b of FIG. 6B (the Q-switching window) centered at time zero, a first Q factor 654a and/or corresponding first attenuation value 654b is set in phase 1. The value of the Q factor 654a (FIG. 6A) or attenuation value 654b (FIG. 6B) in phase 1 is set sufficiently high to allow the onset of lasing 656 (FIG. 6C) to occur (namely, at a level at which the gain of the laser medium exceeds the cavity losses of the laser), and can be set sufficiently low to still provide attenuation to allow power buildup in the laser beyond the power level in non-attenuated continuous lasing, although this is optional as will be explained below. This phase 1 attenuation level 654b (FIG. 6A) (or Q factor 654a (FIG. 6B)) can optionally be adjusted as discussed above to keep the average time of onset (in an initial peak 657) (FIG. 6C) of pre-lasing 656 (FIG. 6C) at or near a desired target time.

Next, in phase 2, a second Q factor 658a (FIG. 6A) or a second attenuation value 658b (FIG. 6B) is set at a level at which cavity loss exceeds medium gain, which level(s) can even be at a minimum Q factor or a maximum attenuation for the given laser 434 (including up to “shuttering” the laser), allowing power buildup in the inversion population of the laser medium 427 to a higher level than if the laser were continuing to lase, at even a low level. The laser output accordingly goes to an essentially zero level 660 (FIG. 6C). Phase 2 can last for a time selected to be sufficiently long, for example in the range of 100 to 900 ns or more, that the stored power in the inversion population reaches a maximum or saturation value during phase 2.

Subsequent to phase 2, in phase 3, a third Q factor 659a (FIG. 6A) such as a maximum Q factor of the laser 434, or a third attenuation value 659b (FIG. 6B) such as a minimum attenuation value of the attenuator 440, is set, allowing a Q-switched pulse 655 (FIG. 6C) to be produced. Because of the higher power level stored in the inversion population of the laser medium 427 (higher small signal gain) during phase 2, the pulse 655 has both higher peak power and shorter duration than in the methods shown in FIGS. 5A-5C, despite having the same repetition rate.

Optionally, between the second and third attenuation values or Q factors, the attenuation can be set during an intermediate phase I to an intermediate value 661b (FIG. 6B) sufficiently low (or to an intermediate Q factor 661a (FIG. 6A) sufficiently high) such that pre-lasing can begin again (namely, to a level at which gain of the medium 427 along the cavity 447 exceeds losses of the cavity 447) just before Q-switching in phase 3, to allow a brief second pre-lase 662 (FIG. 6C) to remove any potential temporal dithering of the of the Q-switched pulse 655 (FIG. 6C).

Soon after the pulse 655 (FIG. 6C) with peak at about time 0, the laser output falls to zero or near zero, even though the Q factor or attenuation value in phase 1 is set, as described above with respect to FIGS. 6A and 6B, at a value sufficient to allow lasing. This is because the large Q-switched pulse 655 consumes virtually all of the stored energy (in the form of population inversion in the laser medium 427) in the laser 434. Only after a duration D1 does enough energy build up again to cause the onset of pre-lasing (or low-level continuous lasing) at an initial peak 657, followed by a relatively low power constant beam 656. Duration D1 is shorter, as mentioned above, with the higher laser efficiency produced by alignment of a cavity mode with the gain peak, and so duration D1 from the Q-switched pulse 655 to the initial pre-lasing peak 657 can be used to maintain single mode operation of the laser, varying the cavity length as needed to minimize D1 as described above. As mentioned with respect to FIG. 5C, in a pulsed laser repeating at a fixed frequency, duration D1 is equivalent to the period of the repetition minus duration D2, so duration D2, from the pre-lasing peak 657 to the peak of Q-switched pulse 655, can also be used, and maximized rather than minimized, to maintain single mode operation.

In contrast to the periodic Q factors or attenuation values of FIGS. 5A and 5B, in FIGS. 6A and 6B the first (the phase 1) Q factor 654a or attenuation value 654b, set to produce more gain than loss in the laser so that pre-lasing can occur, does not remain or extend until Q-switching, now located in phase 3. Instead, before Q-switching, the second Q factor 658a or a second attenuation value 658b is set in phase 2 at a level at which loss exceeds gain, or even at a level to effectively shutter the laser, allowing power (or gain) buildup in the inversion population of the laser medium 427 to increase to a higher level, even as high as to a maximum or saturation value. Accordingly, the power level available in the Q-switched pulse 655 during phase 3 is effectively decoupled from the Q factor 654a or attenuation value 654b of phase 1.

FIG. 6D describes a method of operating a laser 434. The method is described in terms of setting a Q factor of the laser but it will be understood that it applies equivalently to setting an attenuation of the laser. In a step S10 the Q factor of the laser 434 is set to a first Q factor (e.g., 654a of FIG. 6A (in phase 1)) after the laser 434 produces a first pulse 655, such that gain of the laser 434 exceeds losses of the laser 434 to allow the laser 434 to produce a first continuous “pre-lasing” beam 656. After the first continuous beam 656 is produced, i.e., sometime after the onset of the first continuous beam 656 in its initial peak 657, in a step S20 the Q factor is reduced to a second Q factor value (e.g., value 658a (in phase 2)). This stops the lasing of the first continuous beam 656 (as seen at low or zero power output level 660 in the graph of FIG. 6C) and the accompanying drain on power buildup in the inversion population of the laser medium 427 of the laser 434. Next in a step S30 the Q-factor is increased to a value (e.g., value 659a in phase 3), such that the laser 434 produces a pulse 655.

After the laser produces the pulse 655, the process can begin to repeat by setting the attenuation again to the Q factor 654a (in a second or repeated phase 1).

In implementations of the method, the second attenuation value 658b or the second Q factor 658a can shutter the laser. The method can also include, after setting the attenuation to the second attenuation value 658b (in phase 2) and before setting the attenuation to the third attenuation value 659b (in phase 3), lowering the attenuation to an intermediate attenuation value 661b (in intermediate phase I), with the intermediate attenuation value 661b higher than the third attenuation value 659b and low enough to allow the laser 434 to produce a second beam 662.

In implementations of the method, the attenuator 440 can include an optical modulator within or connected to the laser 434. The optical modulator can be an AOM or an EOM. The laser 434 can be a CO₂ laser. The laser can be a seed laser 332, 334 in an extreme ultraviolet (EUV) light source 110, such as a main pulse seed laser 334 in an EUV light source 110.

In additional implementations, setting the attenuation to the second attenuation value 658b can include setting the attenuation to the second attenuation value 658b for a time in the range of 200 to 1000 s or 100 to 1000 ns. Setting the attenuation to the intermediate attenuation value 661b can include setting the attenuation to the intermediate attenuation value 661b for a time in the range of 0 to 300 ns. Setting the attenuation to the third attenuation value 659b can include setting the attenuation to the third value 659b for a time in the range of 400 to 700 ns.

In other additional implementations, the method can include monitoring a duration D1 from the first pulse 655 to the production of the first continuous beam 656, such as represented by the initial peak 657 of the first continuous beam 656, and adjusting a cavity length of the laser to minimize the duration D1. The method can include monitoring duration D1 and adjusting the first attenuation value 654b based on the duration D1. The third attenuation value can be a maximum attenuation value.

In another aspect of the present disclosure, with reference to FIGS. 4, 6B, and 6C, a laser 434 including an optical modulator 440 controlled by a signal 440a applied to the optical modulator 440 can be operated by a method of setting a magnitude of the signal 440a to a first value 654b such that the laser operates in a mode in which laser gain exceeds resonator losses; setting a magnitude of the signal 440a to a second value 658b such that the laser 434 is shuttered; and setting a magnitude of the signal 440a to a third value 659b such that the laser 434 produces a pulse 655.

In implementations, the laser can include an output coupler 441 having a PZT 448, and the method can include a step performed during the step of setting a magnitude of the signal 440a to a first value 654b of using an output of the laser to control a voltage 448a applied to the piezoelectric transducer 448. The optical modulator 440 can include or can be in the form of an AOM or an EOM.

In other aspects, a system for generating a pulse of laser radiation includes a laser 434 including an optical modulator 440 controlled by a signal 440a applied to the optical modulator 440 and a control system 444 configured and adapted to sequentially set a magnitude of the signal 440a to a first value 654b such that the laser 434 operates in a mode in which laser gain exceeds resonator losses, then to set a magnitude of the signal 440a to a second value 658b such that the laser 434 is shuttered, and then set a magnitude of the signal 440a to a third value 659b such that the laser 434 produces a pulse.

In implementations of the system, the laser 434 can include an output coupler 441 having a PZT 448 and wherein the control system 444 is additionally configured and adapted to use an output of the laser 434 when the signal 440a is at the first value 654b to control a voltage 448a applied to the PZT 448.

In additional aspects, and with reference to FIGS. 4 and 6A, a laser system includes a laser 434 having a laser cavity 427, an optical modulator 440 configured to control a Q factor of the laser cavity 447, a power sensor 442 positioned outside the laser cavity 427 and configured to detect a power level of radiation emitted from the laser 434 and to produce power level data and/or signals 442a relating to a power level of radiation emitted from the laser 434, and a control system 444 is connected to receive the power level data and/or signals 442a and to control the optical modulator 440, with the control system 444 configured to (1) set the Q factor of the cavity 427 of the laser 434 to a first value 654a high enough to allow lasing to occur, (2) at a time after lasing occurs, set the Q factor of the cavity 427 to a second value 658a low enough to stop the lasing from occurring, and (3) after setting the Q factor of the cavity 427 to the second value 658a, set the Q factor of the cavity 427 to third value 659a such that the laser 434 emits a pulse.

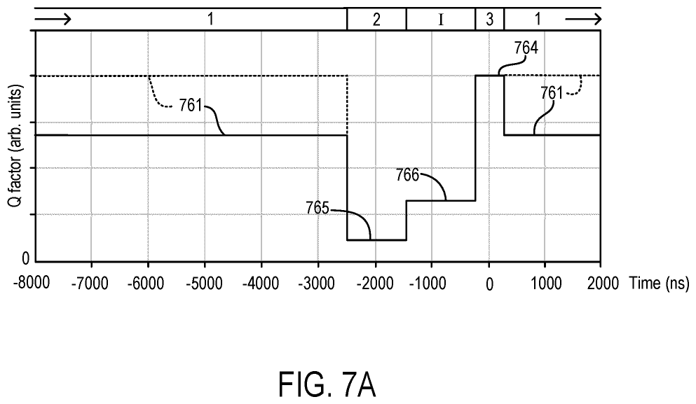

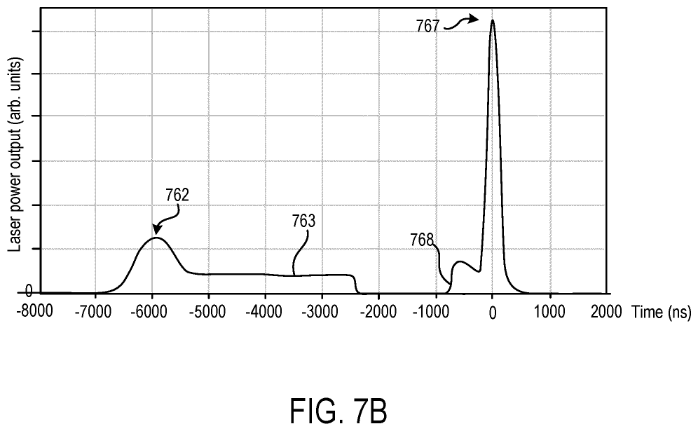

FIGS. 7A and 7B are graphs showing additional implementations and variations of the methods described in reference to FIGS. 6A, 6B, and 6C. FIG. 7A shows the variation(s) of Q factor over time. FIG. 7B shows the resulting laser output power over time.

With reference to FIGS. 7A and 7B, as shown, each phase of phases 1-3 and I can have a different Q factor (and corresponding attenuation). It is not required that any phase's Q factor match another. Also, the Q factor of phase 2 (for energy storage) need not be zero (nor the corresponding attenuation 100%). Because the power available in the Q-switched pulse 767 (FIG. 7B) is decoupled from the first Q factor 761 in phase 1 (FIG. 7A) (as mentioned in connection with FIGS. 6B and 6C above) and thus also from the time of onset of pre-lasing, the first Q factor 761 in phase 1 can be set relatively high, such as by setting an earlier target time for the onset (initial peak 762) of the pre-lasing continuous beam 763, or even by setting the first Q factor 761 equal to the third Q factor 764 in phase 3 (the high Q factor with low or zero attenuation during Q-switching) as shown by the alternate dotted-line value in FIG. 7A for the first Q factor 764.

Increasing the first Q factor 761 can have the effect of producing an earlier and less time-dithered onset 762 of the pre-lasing beam 763, giving more time, if needed or desired, in the inter-pulse interval, such as for energy storage during the second Q factor 765 in phase 2. More time in the inter-pulse interval could also be used for the intermediate phase I, if desired, to ensure that a “second pre-lasing” or continuous beam 768 can reliably arise during the intermediate Q factor 766 and prior to the Q-switched pulse 767, to minimize temporal dither of the Q-switched pulse 767. The intermediate Q factor 766 can also be set lower than a typical lasing threshold and still allow the second pre-lasing or continuous beam 768 to arise, since the laser 434 is at that point in time approaching a lasing threshold from an energy-saturated state, rather than from an energy-depleted state, providing higher initial gain and allowing lasing to begin more easily (and with less temporal dither). In such an implementation, a shift in terms could even be appropriate, with first pre-lasing 763 re-labeled as a “post-lasing” (following immediately after the Q-switched pulse, to allow cavity length and cavity mode optimization), and with second pre-lasing 768 re-labeled simply as “pre-lasing” (coming immediately before the Q-switched pulse to absorb any temporal dithering).

The embodiments can be further described using the following clauses:
1. A method of operating a laser, the method comprising:
after a laser produces a first pulse, setting an attenuation of an attenuator in the laser to a first attenuation value such that gain of the laser exceeds losses of the laser to allow the laser to produce a first continuous beam;
after the first continuous beam is produced, increasing the attenuation of the attenuator to a second attenuation value such that losses of the laser exceed a gain of the laser; and
after increasing the attenuation to the second value, lowering the attenuation of the attenuator to a third attenuation value such that the laser produces a second pulse.
2. The method of clause 1 further comprising, after the laser produces the second pulse, setting the attenuation to the first attenuation value.
3. The method of clause 1 wherein the second value shutters the laser.
4. The method of clause 1 further comprising, after setting the attenuation to the second attenuation value and before setting the attenuation to the third attenuation value, lowering the attenuation to an intermediate attenuation value higher than the third attenuation value and low enough to allow the laser to produce a second beam.
5. The method of clause 1 wherein the attenuator comprises an optical modulator within or connected to the laser.
6. The method of clause 1 wherein the attenuator comprises an acousto-optic modulator (AOM) within or connected to the laser.
7. The method of clause 1 wherein the attenuator comprises an acousto-optic modulator (AOM) within or connected to the laser and wherein setting the attenuation of the attenuator comprises setting an RF power level supplied to the AOM, increasing the attenuation of the attenuator comprises increasing the RF power supplied to the AOM, and lowering the attenuation of the attenuator comprises lowering the RF power supplied to the AOM.
8. The method of clause 1 wherein the attenuator comprises an electro-optic modulator (EOM) within or connected to the laser.
9. The method of clause 1 wherein the laser is a CO₂ laser.
10. The method of clause 1 wherein the laser is a seed laser in an extreme ultraviolet (EUV) light source.
11. The method of clause 1 wherein the laser is a main pulse seed laser in an EUV light source.
12. The method of clause 1 wherein setting the attenuation to the second attenuation value comprises setting the attenuation to the second attenuation value for a time in the range of 100 to 1000 nanoseconds (ns).
13. The method of clause 1 wherein setting the attenuation to the intermediate attenuation value comprises setting the attenuation to the intermediate attenuation value for a time in the range of 0 to 300 ns.
14. The method of clause 1 wherein setting the attenuation to the third attenuation value comprises setting the attenuation to the third value for a time duration in the range of 400 to 700 ns.
15. The method of clause 1 further comprising monitoring a duration from the first pulse to the production of the first continuous beam and adjusting a cavity length of the laser to minimize the duration.
16. The method of clause 1 further comprising monitoring a duration between the first pulse to the production of the first continuous beam and adjusting the first attenuation value based on the duration.
17. The method of clause 1 wherein the third attenuation value is a maximum attenuation value.
18. The method of clause 1 wherein the first attenuation value is equal to the third attenuation value.
19. The method of clause 1 wherein (1) increasing the attenuation of the attenuator to a second attenuation value such that losses of the laser exceed a gain of the laser and, (2) after increasing the attenuation to the second value, lowering the attenuation of the attenuator to a third attenuation value such that the laser produces a second pulse, comprises Q-switching the laser.
20. A method of operating a laser including an optical modulator controlled by a signal applied to the optical modulator, the method comprising:
setting a magnitude of the signal to a first value such that the laser operates in a mode in which laser gain exceeds resonator losses;
setting a magnitude of the signal to a second value such that the laser is shuttered; and
setting a magnitude of the signal to a third value such that the laser produces a pulse.
21. The method of clause 20 wherein the laser includes an output coupler having a piezoelectric transducer and further comprising using an output of the laser to control a voltage applied to the piezoelectric transducer during the step of setting a magnitude of the signal to a first value.
22. The method of clause 20 wherein the optical modulator comprises an acousto-optic modulator (AOM).
23. The method of clause 20 wherein the optical modulator comprises an acousto-optic modulator (AOM) and the signal comprises an RF power level.
24. The method of clause 20 wherein the optical modulator comprises an electro-optic modulator (EOM).
25. The method of clause 20 wherein (1) setting a magnitude of the signal to a second value such that the laser is shuttered, and (2) setting a magnitude of the signal to a third value such that the laser produces a pulse, comprises Q-switching the laser.
26. A system for generating a pulse of laser radiation, the system comprising:
a laser including an optical modulator controlled by a signal applied to the optical modulator; and
a control system configured and adapted to sequentially set a magnitude of the signal to a first value such that the laser operates in a mode in which laser gain exceeds resonator losses, then to set a magnitude of the signal to a second value such that the laser is shuttered, and then set a magnitude of the signal to a third value such that the laser produces a pulse.
27. The system of clause 26 wherein the laser includes an output coupler having a piezoelectric transducer and wherein the control system is additionally configured and adapted to use an output of the laser when the signal is at the first value to control a voltage applied to the piezoelectric transducer.
28. The system of clause 26 wherein the optical modulator comprises an acousto-optic modulator (AOM).
29. The system of clause 26 wherein the optical modulator comprises an acousto-optic modulator (AOM) and the signal applied to the optical modulator comprises an RF power level.
30. The system of clause 26 wherein the optical modulator comprises an electro-optic modulator (EOM).
31. The system of clause 26 wherein the control system is configured and adapted to perform Q-switching.
32. A laser system comprising:
a laser having a laser cavity;
an optical modulator configured to control a Q factor of the laser cavity;
a power sensor positioned outside the laser cavity and configured to detect a power level of radiation emitted from the laser and to produce power level data and/or signals relating to a power level of radiation emitted from the laser; and
a control system connected to receive the power level data or signals and to control the optical modulator, the control system configured to (1) set the Q factor of the cavity of the laser to a first value high enough to allow lasing to occur, (2) at a time after lasing is detected by the power sensor, set the Q factor of the cavity to a second value less than the second value and low enough to stop the lasing from occurring, and (3) after setting the Q factor of the cavity to the second value, set the Q factor of the cavity to a third value such that the laser emits a pulse.
33. The laser system of clause 32 wherein the control system is configured to perform Q-switching.

The above-described implementations and other implementations are within the scope of the following claims.

1. A method of operating a laser, the method comprising:
after a laser produces a first pulse, setting an attenuation of an attenuator in the laser to a first attenuation value such that gain of the laser exceeds losses of the laser to allow the laser to produce a first continuous beam;
after the first continuous beam is produced, increasing the attenuation of the attenuator to a second attenuation value such that losses of the laser exceed a gain of the laser; and
after increasing the attenuation to the second value, lowering the attenuation of the attenuator to a third attenuation value such that the laser produces a second pulse.

2. The method of claim 1 further comprising, after the laser produces the second pulse, setting the attenuation to the first attenuation value.

3. The method of claim 1 wherein the second value shutters the laser.

4. The method of claim 1 further comprising, after setting the attenuation to the second attenuation value and before setting the attenuation to the third attenuation value, lowering the attenuation to an intermediate attenuation value higher than the third attenuation value and low enough to allow the laser to produce a second beam.

5. (canceled)

6. (canceled)

7. The method of claim 1 wherein the attenuator comprises an acousto-optic modulator (AOM) within or connected to the laser and wherein setting the attenuation of the attenuator comprises setting an RF power level supplied to the AOM, increasing the attenuation of the attenuator comprises increasing the RF power supplied to the AOM, and lowering the attenuation of the attenuator comprises lowering the RF power supplied to the AOM.

8. The method of claim 1 wherein the laser is a CO₂ laser and wherein the attenuator comprises an electro-optic modulator (EOM) within or connected to the laser.

9. (canceled)

10. (canceled)

11. The method of claim 1 wherein the laser is a main pulse seed laser in an EUV light source.

12. The method of claim 1 wherein setting the attenuation to the second attenuation value comprises setting the attenuation to the second attenuation value for a time in the range of 100 to 1000 nanoseconds (ns).

13. The method of claim 1 wherein setting the attenuation to the intermediate attenuation value comprises setting the attenuation to the intermediate attenuation value for a time in the range of 0 to 300 ns, and wherein setting the attenuation to the third attenuation value comprises setting the attenuation to the third value for a time duration in the range of 400 to 700 ns.

14. (canceled)

15. The method of claim 1 further comprising monitoring a duration from the first pulse to the production of the first continuous beam and adjusting a cavity length of the laser to minimize the duration.

16. The method of claim 1 further comprising monitoring a duration between the first pulse to the production of the first continuous beam and adjusting the first attenuation value based on the duration.

17. (canceled)

18. The method of claim 1 wherein the first attenuation value is equal to the third attenuation value.

19. The method of claim 1 wherein (1) increasing the attenuation of the attenuator to a second attenuation value such that losses of the laser exceed a gain of the laser and, (2) after increasing the attenuation to the second value, lowering the attenuation of the attenuator to a third attenuation value such that the laser produces a second pulse comprises Q-switching the laser.

20. A method of operating a laser including an optical modulator controlled by a signal applied to the optical modulator, the method comprising:
setting a magnitude of the signal to a first value such that the laser operates in a mode in which laser gain exceeds losses in a resonator of the laser;
setting a magnitude of the signal to a second value such that the laser is shuttered; and
setting a magnitude of the signal to a third value such that the laser produces a pulse.

21. The method of claim 20 wherein the laser includes an output coupler having a piezoelectric transducer, the method further comprising using an output of the laser to control a voltage applied to the piezoelectric transducer during the step of setting a magnitude of the signal to a first value.

22. (canceled)

23. The method of claim 20 wherein the optical modulator comprises an acousto-optic modulator (AOM) and the signal comprises an RF power level.

24. (canceled)

25. The method of claim 20 wherein (1) setting a magnitude of the signal to a second value such that the laser is shuttered, and (2) setting a magnitude of the signal to a third value such that the laser produces a pulse comprises Q-switching the laser.

26. A system for generating a pulse of laser radiation, the system comprising:
a laser including an optical modulator controlled by a signal applied to the optical modulator; and
a control system configured and adapted to sequentially set a magnitude of the signal to a first value such that the laser operates in a mode in which laser gain exceeds losses in a resonator of the laser, then to set a magnitude of the signal to a second value such that the laser is shuttered, and then set a magnitude of the signal to a third value such that the laser produces a pulse.

27. The system of claim 26 wherein the laser includes an output coupler having a piezoelectric transducer and wherein the control system is additionally configured and adapted to use an output of the laser when the signal is at the first value to control a voltage applied to the piezoelectric transducer.

28. The system of claim 26 wherein the optical modulator comprises an acousto-optic modulator (AOM).

29. The system of claim 26 wherein the optical modulator comprises an acousto-optic modulator (AOM) and the signal applied to the optical modulator comprises an RF power level.

30. The system of claim 26 wherein the optical modulator comprises an electro-optic modulator (EOM).

31. The system of claim 26 wherein the control system is configured and adapted to perform Q-switching.

32. A laser system comprising:
a laser having a laser cavity;
an optical modulator configured to control a Q factor of the laser cavity;
a power sensor positioned outside the laser cavity and configured to detect a power level of radiation emitted from the laser and to produce power level data and/or signals relating to a power level of radiation emitted from the laser; and
a control system connected to receive the power level data or signals and to control the optical modulator, the control system configured to (1) set the Q factor of the cavity of the laser to a first value high enough to allow lasing to occur, (2) at a time after lasing is detected by the power sensor, set the Q factor of the cavity to a second value less than the second value and low enough to stop the lasing from occurring, and (3) after setting the Q factor of the cavity to the second value, set the Q factor of the cavity to a third value such that the laser emits a pulse.

33. The laser system of claim 32 wherein the control system is configured to perform Q-switching.
